(19) United States
(12) Patent Application Publication
(10) Pub. No.: US 2026/0066216 A1
(43) Pub. Date: Mar. 5, 2026

(54) ELECTRON MICROSCOPE AND CONTROL METHOD THEREOF

(71) Applicant: HITACHI, LTD., Tokyo (JP)

(72) Inventors: Yoshio Takahashi, Tokyo (JP); Tetsuya Akashi, Tokyo (JP)

(73) Assignee: HITACHI, LTD., Tokyo (JP)

(21) Appl. No.: 19/298,888

(22) Filed: Aug. 13, 2025

(30) Foreign Application Priority Data
Sep. 2, 2024 (JP) 2024-150672

(51) Int. Cl. H01J 37/22; H01J 37/147; H01J 37/244; H01J 37/26; H01J 37/28

(52) U.S. Cl. CPC H01J 37/222; H01J 37/1474; H01J 37/244; H01J 37/265; H01J 37/28

(57) ABSTRACT

An electron microscope includes: an electron source configured to emit an electron beam with which a sample is irradiated; a detector configured to detect an electron emitted from the sample and a sample peripheral object disposed around the sample; and a control unit configured to acquire an observation image based on a detection signal output from the detector. The control unit acquires the observation image for each of directions of the electron beam by controlling the direction of the electron beam with respect to the sample, and removes an image of the sample peripheral object from the observation image using an averaged image obtained by averaging the observation images.

### CLAIM OF PRIORITY

The present application claims priority from Japanese Patent Application JP 2024-150672 filed on Sep. 2, 2024, the content of which is hereby incorporated by reference into this application.

### BACKGROUND OF THE INVENTION

### 1. Field of the Invention

The present invention relates to an electron microscope used for observing a sample disposed in a capsule in which a gas or a liquid is sealed, and a control method thereof.

### 2. Description of Related Art

An electron microscope is a device that detects secondary electrons, reflected electrons, and transmitted electrons generated by irradiating a sample disposed in a vacuum with an electron beam, and generates an observation image of the sample based on a detection signal. When a sample in a gas or a liquid is to be observed, the sample is disposed in a capsule in which the gas or the liquid is sealed. However, when the capsule is used, not only the sample but also the capsule is irradiated with the electron beam, and thus the observation image includes not only the sample but also the capsule. The capsule included in the observation image hinders the observation of the sample, and thus is preferably removed.

PTL 1 discloses that amplitude information and phase information are reproduced from a plurality of hologram images acquired by changing an incident angle of an electron beam, and a capsule is separated and removed by an analysis algorithm of electron beam tomography.

### CITATION LIST

### Patent Literature

PTL 1: WO 2023/223538

### SUMMARY OF THE INVENTION

However, in PTL 1, in order to separate and remove the capsule, it is essential to reproduce the phase information from the hologram image or the like. In order to reproduce the phase information, it is necessary to provide an electron biprism or the like, but since a general electron microscope does not include the electron biprism or the like, it is difficult to reproduce the phase information.

Therefore, an object of the invention is to provide an electron microscope capable of removing a capsule from an observation image without reproducing phase information, and a control method thereof.

In order to achieve the above object, the invention provides an electron microscope including: an electron source configured to emit an electron beam with which a sample is irradiated; a detector configured to detect an electron emitted from the sample and a sample peripheral object disposed around the sample; and a control unit configured to acquire an observation image based on a detection signal output from the detector. The control unit acquires the observation image for each of directions of the electron beam by controlling the direction of the electron beam with respect to the sample, and removes an image of the sample peripheral object from the observation image using an averaged image obtained by averaging the observation images.

Further, the invention provides a control method of an electron microscope including an electron source configured to emit an electron beam with which a sample is irradiated, a detector configured to detect an electron emitted from the sample and a sample peripheral object disposed around the sample, and a control unit configured to acquire an observation image based on a detection signal output from the detector, and the control method includes: the control unit acquiring the observation image for each of directions of the electron beam by controlling the direction of the electron beam with respect to the sample, and removing an image of the sample peripheral object from the observation image using an averaged image obtained by averaging the observation images.

According to the invention, it is possible to provide an electron microscope capable of removing a capsule from an observation image without reproducing phase information, and a control method thereof.

### BRIEF DESCRIPTION OF THE DRAWINGS

FIG. 1 is an overall configuration diagram of an electron microscope according to Embodiment 1.

FIG. 2 shows an example of an observation image of a sample disposed in a capsule.

FIG. 3 is a diagram showing an example of a flow of a process according to Embodiment 1.

FIG. 4 is a diagram showing a direction of an electron beam with respect to the sample.

FIG. 5 shows that the direction of the electron beam with respect to the sample is set by a sample stage.

FIG. 6 is a diagram supplementing FIG. 3.

FIG. 7 is a diagram showing another example of the flow of the process according to Embodiment 1.

FIG. 8 is a diagram supplementing FIG. 7.

FIG. 9 is an overall configuration diagram of an electron microscope according to Embodiment 2.

### DESCRIPTION OF EMBODIMENTS

Hereinafter, embodiments of an electron microscope according to the invention will be described with reference to the accompanying drawings. The electron microscope is a device that detects secondary electrons, reflected electrons, and transmitted electrons generated from a sample by irradiating the sample with an electron beam, and generates an observation image based on a detection signal. A sample peripheral object other than the sample may be disposed around the sample. That is, the sample peripheral object is not an observation target, but is, for example, a capsule, a film, a sheet, a mesh, a transmission window, a membrane, or the like.

### Embodiment 1

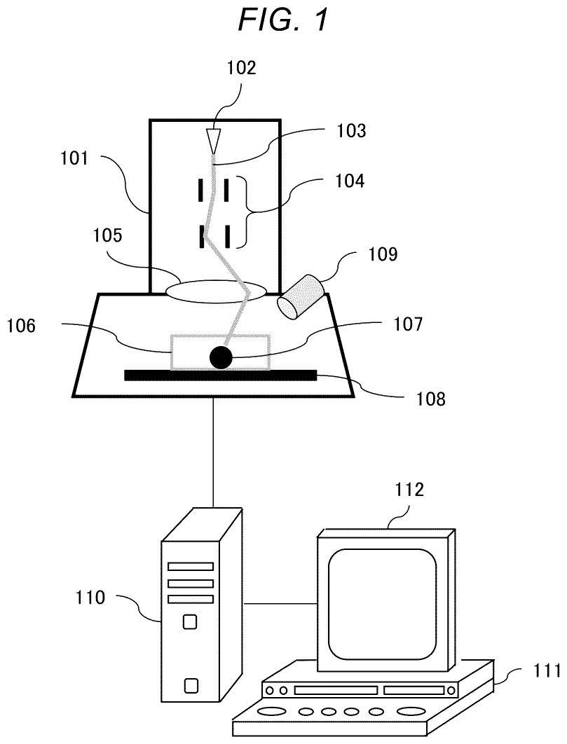

An overall configuration of a scanning electron microscope as an electron microscope according to Embodiment 1 will be described with reference to FIG. 1. The scanning electron microscope includes a microscope body 101 and a control unit 110.

The microscope body 101 includes an electron source 102, a deflector 104, a converging lens 105, a sample stage 108, and a detector 109. An inside of the microscope body 101 is evacuated by a vacuum pump or the like, and a capsule 106 in which a gas or a liquid is sealed together with the sample 107 is held on the sample stage 108. The capsule 106 is an example of the sample peripheral object.

The electron source 102 emits an electron beam 103 with which the capsule 106 and the sample 107 are irradiated. The deflector 104 deflects the electron beam 103 in a manner of scanning an observation region. The converging lens 105 converges the deflected electron beam 103 on the observation region. The sample stage 108 holding the capsule 106 containing the sample 107 moves in a horizontal direction or in a vertical direction to set the observation region at a predetermined position. The sample stage 108 is tilted as necessary. The detector 109 detects secondary electrons or reflected electrons emitted from the capsule 106 and the sample 107 due to the irradiation with the electron beam 103, and transmits a detection signal to the control unit 110.

The control unit 110 is, for example, a computer, generates an observation image based on the detection signal transmitted from the detector 109, and controls operations of the units provided in the microscope body 101. A storage unit 111 and a display unit 112 are connected to the control unit 110. The storage unit 111 is, for example, a hard disk drive (HDD) or a solid state drive (SSD), and stores various data related to generation of observation images and control of an operation of each unit, the observation images, and various images generated using the observation images. The display unit 112 is, for example, a liquid crystal display, and displays the observation images and various images.

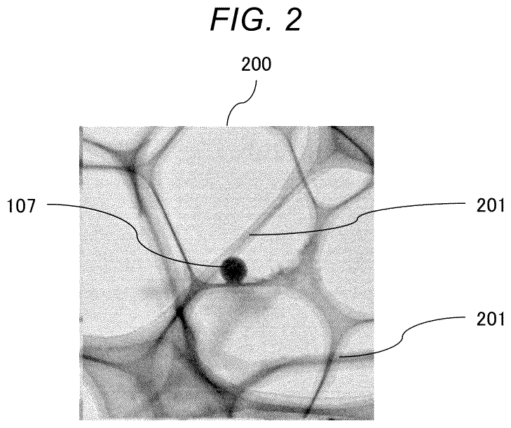

An example of an observation image of the sample 107 disposed in the capsule 106 will be described with reference to FIG. 2. The capsule 106 is formed of a carbon film reinforced by a microgrid, and the sample 107 is a latex sphere. An observation image 200 shown in FIG. 2 includes a reticulate microgrid 201 together with the black-circle-shaped sample 107 located at a center. A carbon film which is a light element and has a small film thickness is not included in the observation image 200.

The microgrid 201 included in the observation image 200 becomes noise when the sample 107 is observed, and hinders the observation of the sample 107. Therefore, in Embodiment 1, an observation image is acquired for each direction of the electron beam 103 by controlling the direction of the electron beam 103 with respect to the sample 107, and a sample image from which the capsule 106 is removed is generated using an averaged image obtained by averaging a plurality of the acquired observation images.

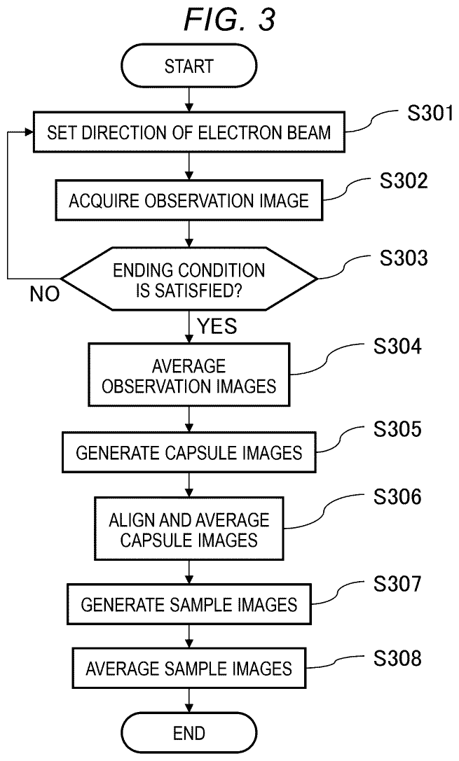

An example of a flow of a process of Embodiment 1 will be described for each processing step with reference to FIG. 3.

### S301

The control unit 110 sets the direction of the electron beam 103 with respect to the sample 107 by controlling the deflector 104. Specifically, the direction of the electron beam 103 with respect to the sample 107 is set by the control unit 110 controlling a current or a voltage supplied to the deflector 104 which is a coil or an electrode pair.

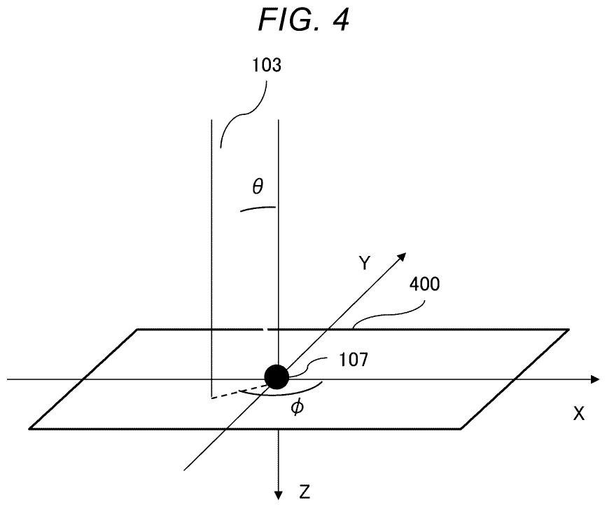

The direction of the electron beam 103 with respect to the sample 107 will be described with reference to FIG. 4. It is assumed that a sample surface 400 including the observation region is a surface including an X-axis and a Y-axis, and an axis orthogonal to the sample surface 400 is a Z-axis. The direction of the electron beam 103 with respect to the sample 107 is determined by an incident angle θ and an azimuth angle φ. The incident angle θ is an angle formed by the Z-axis and the electron beam 103, and the azimuth angle φ is an angle formed by the electron beam 103 projected onto an XY plane and the X-axis. The electron beam 103 projected onto the XY plane is indicated by a dotted line in FIG. 4.

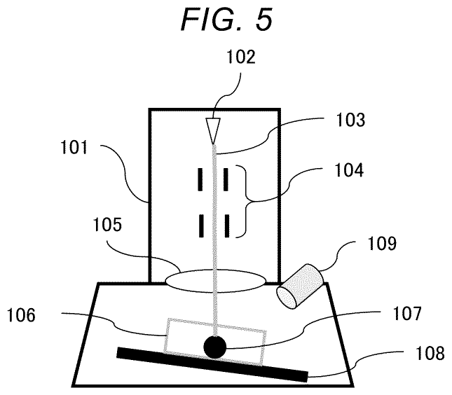

As shown in FIG. 5, the direction of the electron beam 103 with respect to the sample 107 may be set by tilting the sample stage 108. A tilted angle of the sample stage 108 is controlled by the control unit 110. When the sample stage 108 is used to set the direction of the electron beam 103, the direction of the electron beam 103 can be set in a wider range, and an influence of an aberration of the converging lens 105 can be reduced. When the deflector 104 is used to set the direction of the electron beam 103, the direction of the electron beam 103 can be set more finely.

### S302

The control unit 110 acquires the observation image in the direction of the electron beam 103 with respect to the sample 107 set in S301. The acquired observation image is stored in the storage unit 111.

### S303

The control unit 110 determines whether an ending condition is satisfied. If the ending condition is satisfied, the process proceeds to S304, and if the ending condition is not satisfied, the process returns to S301. That is, the setting of the direction of the electron beam 103 in S301 and the acquisition of the observation image in S302 are repeated until the ending condition is satisfied.

The ending condition is, for example, that the number of observation images acquired for each direction of the electron beam 103 exceeds a predetermined number, or that a time required for setting the direction of the electron beam 103 and acquiring the observation images exceeds a predetermined time. The ending condition may be that an operator issues a command to end repetition of S301 and S302.

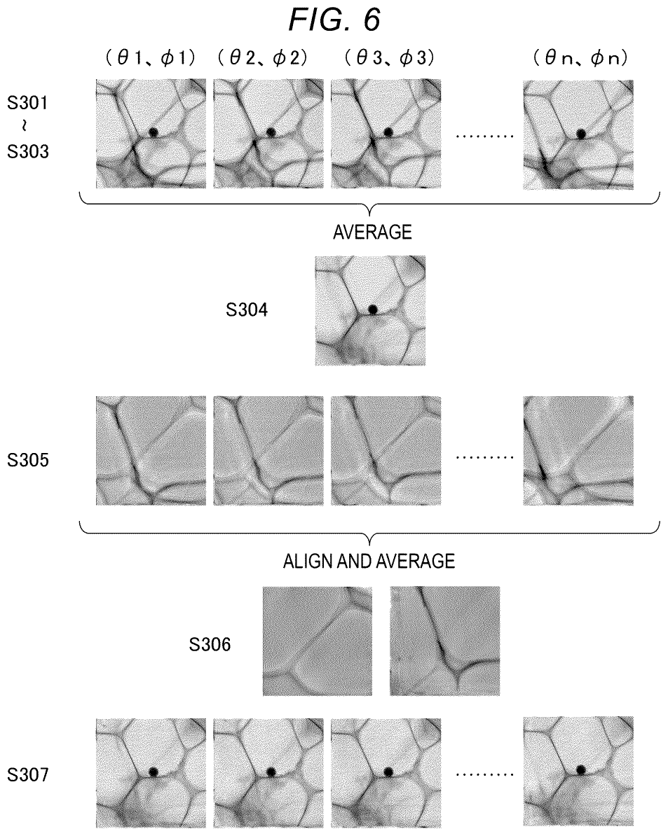

FIG. 6 shows a plurality of observation images acquired in S301 to S303. Since the incident angle θ and the azimuth angle q are different in each observation image, a position of the reticulate microgrid with respect to the black-circle-shaped sample is different. The plurality of observation images may be acquired by changing only the incident angle θ while keeping the azimuth angle q constant. When only the incident angle θ is changed, the setting of the direction of the electron beam 103 with respect to the sample 107 can be simplified.

### S304

The control unit 110 generates the averaged image by averaging the plurality of observation images acquired in S301 to S303. Prior to the generation of the averaged image, alignment processing using a part of the sample 107 as a reference may be performed on each of the plurality of observation images. For example, template matching is used for the alignment processing.

FIG. 6 shows an averaged image generated in S304. The microgrids at different positions with respect to the sample 107 in the observation images are dispersed and unclear in the averaged image. On the other hand, since the sample 107 is at the same position in the observation images, the sample 107 is clear in the averaged image. Further, in the averaged image generated after the alignment processing performed on the observation images, the sample 107 becomes clearer.

### S305

The control unit 110 generates a plurality of capsule images by subtracting the averaged image generated in S304 from each of the plurality of observation images acquired in S301 to S303. That is, by subtracting the averaged image in which the sample 107 is clear and the microgrid is unclear from each of the observation images, the capsule images in each of which the sample 107 is removed and the capsule 106 is imaged are generated.

FIG. 6 shows the plurality of capsule images generated in S305. Each capsule image includes only the microgrid, which is a part of the capsule 106, and does not include the sample 107. Since the positions of the microgrids are different in the observation images, the positions of the microgrids are also different in the capsule images. Each capsule image includes a microgrid of an upper capsule which is the capsule 106 located closer to the electron source 102 than is the sample 107 and a microgrid of a lower capsule which is the capsule 106 located closer to the sample stage 108 than is the sample 107.

### S306

The control unit 110 generates an upper capsule image and a lower capsule image by performing the alignment processing on the plurality of capsule images generated in S305 and then averaging the images. The upper capsule image is generated by performing the alignment processing on the plurality of capsule images based on the microgrid of the upper capsule and then averaging the images. The lower capsule image is generated by performing the alignment processing on the plurality of capsule images based on the microgrid of the lower capsule and then averaging the images. For example, the template matching is used for the alignment processing.

FIG. 6 shows the upper capsule image and the lower capsule image generated in S306. The upper capsule image includes the microgrid of the upper capsule located closer to the electron source 102 than the sample 107 is, and the lower capsule image includes the microgrid of the lower capsule located closer to the sample stage 108 than the sample 107 is.

### S307

The control unit 110 generates a plurality of sample images by subtracting the upper capsule image and the lower capsule image generated in S306 from each of the plurality of observation images acquired in S301 to S303. That is, the upper capsule image including the microgrid of the upper capsule, and the lower capsule image including the microgrid of the lower capsule are subtracted from each of the observation images to generate the sample image from which the capsule 106 is removed. It is not essential to generate a plurality of sample images, and a single sample image may be generated by subtracting the upper capsule image and the lower capsule image from any of the plurality of observation images.

FIG. 6 shows the plurality of sample images generated in S307. In each of the sample images, the microgrids of the upper capsule and the lower capsule are removed, and the sample 107 is more clearly imaged.

### S308

The control unit 110 averages the plurality of sample images generated in S307 to reduce noise included in the sample images. Note that, S308 is not essential, and S308 is skipped when a single sample image is generated in S307.

According to the flow of the process described with reference to FIG. 3, the sample image in which the microgrid is removed from the observation image including the sample 107 together with the microgrid which is a part of the capsule 106 is generated. By removing the microgrid, the sample 107 can be observed in detail.

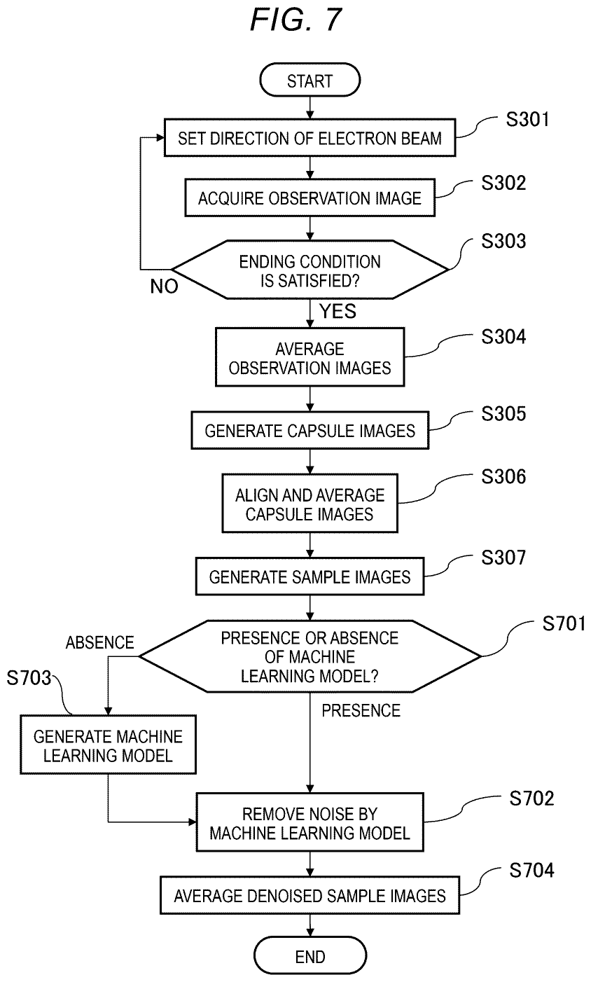

Another example of the flow of the process according to Embodiment 1 will be described with reference to FIG. 7. Since S301 to S307 are the same as those in FIGS. 3, S701 to S704 for replacing S308 will be described below.

### S701

The control unit 110 determines the presence or absence of a machine learning model that learns noise removal. If the machine learning model is present, the process proceeds to S702, and if the machine learning model is absent, the process proceeds to S702 through S703.

### S702

The control unit 110 generates a plurality of denoised sample images by executing noise removal using the machine learning model on each of the plurality of sample images generated in S307. It is not essential to generate a plurality of denoised sample images, and a single denoised sample image may be generated by executing the noise removal using the machine learning model on any of the plurality of observation images.

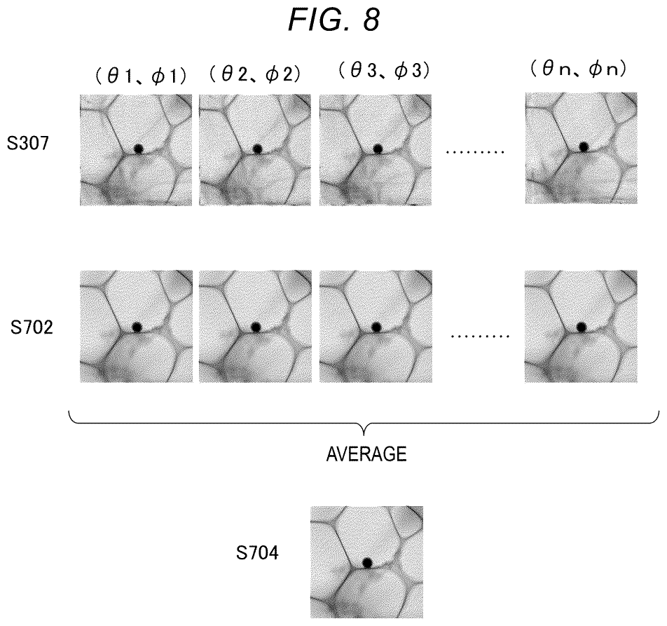

FIG. 8 shows the plurality of sample images generated in S307 together with the plurality of denoised sample images generated in S702. In each of the denoised sample images from which granular noise included in the sample image is removed, the sample 107 is more clearly imaged.

### S703

The control unit 110 generates the machine learning model for executing the noise removal. As the machine learning model, DuCNN, Deep Image Prior, Noise2Noise, Noise2Void, or the like is used. In generation of the machine learning model, the plurality of sample images generated in S307 are used as an input image and a supervised image. The generated machine learning model is stored in the storage unit 111.

### S704

The control unit 110 further reduces the noise remaining in the denoised sample images by averaging the plurality of denoised sample images generated in S702. Note that, S704 is not essential, and S704 is skipped when the single denoised sample image is generated in S702.

According to the flow of the process described with reference to FIG. 8, as in FIG. 3, the sample image in which the microgrid is removed from the observation image including the sample 107 together with the microgrid which is a part of the capsule 106 is generated. By removing the microgrid, the sample 107 can be observed in detail.

In addition, since the noise removal using the machine learning model is executed on the sample image from which the microgrid is removed, the denoised sample image in which the sample 107 is more clearly imaged can be generated. Further, by averaging the plurality of denoised sample images, the noise can be further reduced.

### Embodiment 2

Embodiment 1 discloses that a signal derived from the capsule is removed from the observation image acquired by the scanning electron microscope. In Embodiment 2, removal of a signal derived from a capsule from an observation image acquired by a transmission electron microscope will be described.

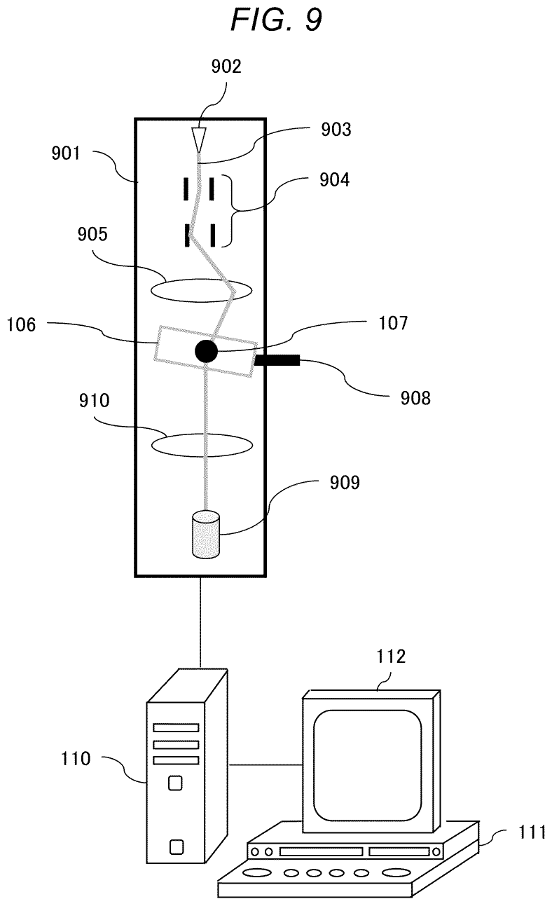

An overall configuration of the transmission electron microscope as an electron microscope according to Embodiment 2 will be described with reference to FIG. 9. The transmission electron microscope includes a microscope body 901 and the control unit 110.

The microscope body 901 includes an electron source 902, a deflector 904, a condenser lens 905, a sample stage 908, an objective lens 910, and a detector 909. An inside of the microscope body 901 is evacuated by a vacuum pump or the like, and the capsule 106 in which a gas or a liquid is sealed together with the sample 107 is held on the sample stage 908.

The electron source 902 emits an electron beam 903 with which the capsule 106 and the sample 107 are irradiated. The deflector 904 sets a direction of the electron beam 903 with respect to the sample 107 by deflecting the electron beam 903. The condenser lens 905 shapes the electron beam 903. The sample stage 908 holding the capsule 106 containing the sample 107 moves in the horizontal direction or in the vertical direction to set an observation region at a predetermined position. The sample stage 908 is tilted to set the direction of the electron beam 903 with respect to the sample 107. The objective lens 910 enlarges transmitted electrons, which are electrons obtained by the electron beam 903 transmitting through the capsule 106 and the sample 107, and images the transmitted electrons on the detector 909. The detector 909 detects the transmitted electrons, and transmits a detection signal to the control unit 110.

The control unit 110 is, similar to that of Embodiment 1, for example, a computer, generates an observation image of the sample 107 based on the detection signal transmitted from the detector 909, and controls operations of the units provided in the microscope body 901.

A flow of a process according to Embodiment 2 is similar to that of Embodiment 1, and is shown in FIG. 3 or FIG. 7. That is, the direction of the electron beam 903 with respect to the sample 107 is set by the control unit 110 controlling the deflector 904 and the sample stage 908, and the sample image from which the capsule 106 is removed is generated using an averaged image of the observation images acquired for directions of the electron beam 903. In addition, a denoised sample image is generated by noise removal using a machine learning model. Further, the noise is further reduced by averaging a plurality of the denoised sample images.

A plurality of embodiments of the electron microscope of the invention have been described above. The invention is not limited to the above embodiments, and can be embodied by modifying components in a range not departing from the gist of the invention. A plurality of components disclosed in the above embodiments may be combined appropriately. A part of components may be deleted from all components disclosed in the above embodiments.

What is claimed is:

1. An electron microscope comprising:
an electron source configured to emit an electron beam with which a sample is irradiated;
a detector configured to detect an electron emitted from the sample and a sample peripheral object disposed around the sample; and
a control unit configured to acquire an observation image based on a detection signal output from the detector, wherein
the control unit acquires the observation image for each of directions of the electron beam by controlling the direction of the electron beam with respect to the sample, and removes an image of the sample peripheral object from the observation image using an averaged image obtained by averaging the observation images.

2. The electron microscope according to claim 1, wherein
the control unit controls the direction of the electron beam with respect to the sample using a deflector configured to deflect the electron beam.

3. The electron microscope according to claim 1, wherein
the control unit controls the direction of the electron beam with respect to the sample by tilting a sample stage holding the sample.

4. The electron microscope according to claim 1, wherein
the direction of the electron beam with respect to the sample is determined by an incident angle and an azimuth angle of the electron beam.

5. The electron microscope according to claim 4, wherein
the control unit keeps the azimuth angle constant and changes the incident angle.

6. The electron microscope according to claim 1, wherein
the control unit generates a plurality of the images of the sample peripheral object by subtracting the averaged image from each of the observation images acquired for the corresponding direction of the electron beam, generates an upper sample peripheral object image and a lower sample peripheral object image by averaging the plurality of images of the sample peripheral object which are subjected to alignment processing, and generates a sample image by subtracting the upper sample peripheral object image and the lower sample peripheral object image from the observation image.

7. The electron microscope according to claim 6, wherein
the control unit generates a plurality of the sample images by subtracting the upper sample peripheral object image and the lower sample peripheral object image from each of the observation images, and reduces noise by averaging the plurality of sample images.

8. The electron microscope according to claim 6, wherein
the control unit removes noise from the sample image using a machine learning model for noise removal.

9. The electron microscope according to claim 8, wherein
the control unit generates a plurality of the sample images by subtracting the upper sample peripheral object image and the lower sample peripheral object image from each of the observation images, and uses the plurality of sample images to generate the machine learning model.

10. The electron microscope according to claim 1, wherein
the sample peripheral object is a capsule in which the sample is sealed, a film covering the sample, or a sample covering of the sample.

11. A control method of an electron microscope including
an electron source configured to emit an electron beam with which a sample is irradiated,
a detector configured to detect an electron emitted from the sample and a sample peripheral object disposed around the sample, and
a control unit configured to acquire an observation image based on a detection signal output from the detector, the control method comprising:
the control unit acquiring the observation image for each of directions of the electron beam by controlling the direction of the electron beam with respect to the sample, and removing an image of the sample peripheral object from the observation image using an averaged image obtained by averaging the observation images.
